(19) United States
(12) Patent Application Publication
(10) Pub. No.: US 2018/0046035 A1
(43) Pub. Date: Feb. 15, 2018

(54) MANUFACTURE METHOD OF LIQUID CRYSTAL DISPLAY PANEL

(71) Applicant: Shenzhen China Star Optoelectronics Technology Co., Ltd., Shenzhen City (CN)

(72) Inventors: Song Lan, Shenzhen City (CN); Yungjui Lee, Shenzhen City (CN); Tao Hu, Shenzhen City (CN)

(21) Appl. No.: 15/026,599

(22) PCT Filed: Feb. 26, 2016
(86) PCT No.: PCT/CN2016/074623

§ 371 Date: Mar. 31, 2016

(30) Foreign Application Priority Data
Feb. 1, 2016 (CN) 201610071589.3

(51) Int. Cl. G02F 1/1337; C09K 19/56; C08G 61/12; G02F 1/1343; H01L 29/66

(52) U.S. Cl. CPC G02F 1/133784; G02F 1/133703; G02F 1/133707; G02F 1/1343; H01L 29/66742; C08G 61/126; C09K 19/56

(57) ABSTRACT

The present invention provides a manufacture method of a liquid crystal display panel. The graphene/PEDOT:PSS composite transparent conductive films replace the traditional ITO transparent conductive films, and a polar material is mixed in the liquid crystal compound of the liquid crystal display panel. The structural formula of the polar material is A-B, wherein the main function of the head group A is to create the larger intermolecular force between the polar material and the graphene/PEDOT:PSS composite transparent conductive films, and the main function of the tail group B is similar with the function of the PI branch to vertically align the liquid crystal molecules in the steric hindrance manner to act the effect of the vertical alignment; i.e. the polar material can generate a larger intermolecular force with the graphene/PEDOT:PSS composite transparent conductive films, and is vertically aligned on the TFT substrate and the CF substrate.

### FIELD OF THE INVENTION

The present invention relates to a display technology field, and more particularly to a manufacture method of a liquid crystal display panel.

### BACKGROUND OF THE INVENTION

The TFT-LCD (Thin Film Transistor Liquid Crystal Display) possesses advantages of thin body, power saving and no radiation to be widely used in many application scopes. Most of the TFT-LCDs on the present market are back light type liquid crystal displays, which comprise a liquid crystal display panel and a back light module. The working principle of the liquid crystal display panel is to locate liquid crystal molecules between two parallel glass substrates. The light of back light module is reflected to generate images by applying driving voltages to control whether the liquid crystal molecules to be changed directions.

Generally, the liquid crystal display panel comprises a CF (Color Filter) substrate, a Thin Film Transistor (TFT) substrate, a LC (Liquid Crystal) sandwiched between the CF substrate and the TFT substrate and sealant. In the TFT-LCD display, the classifications based on the liquid crystal operation mode comprise: phase change (PC), twisted nematic (TN), super twisted nematic (STN), Vertical Alignment (VA) and In plane Switching (IPS). For the common Vertical Alignment display mode, one layer of transparent conductive film needs to be respectively prepared at sides of the CF substrate, the TFT substrate facing the liquid crystal layer at the same time. The main function of the transparent conductive films is to form an electrical field between the CF substrate and the TFT substrate to drive the liquid crystal molecules to twist, and for realizing the bright and dark displays.

At present, the transparent conductive film is an Indium Tin Oxide (ITO) thin film manufactured by the physical vapor deposition (PVD) method. The specific manufacture procedure is: in the PVD device, the strong electrical current bombards the ITO target material to depose the transparent ITO thin film on the substrate. Because the physical property of the ITO oxidation itself, the ITO thin film cannot have bendable property as being acted with a certain external force, which restricts the application in the flexible panel and the wearable device. On the other hand, according to the national policy, the cost of Indium gradually increases, too. Therefore, searching the ITO substitute, of which has high conductivity, high transmission rate, easy manufacture method, and abound resources has the significant meaning and value.

Besides, in the liquid crystal display panel, a layer of alignment film needs to be formed on the thin film transistor substrate and a color film substrate respectively. After the alignment film contacts with the LC, it can make the LC have a pre-tilted angle in certain direction, and thus provide a loading angle (the pre-tilted angle has significant influence to the driving voltage, contrast, response time and view angle of the TFT-LCD) for the liquid crystal molecules. Polyimide (PI) is commonly chosen to be the material of the alignment film, which mainly has rubbing alignment type IP material and lighting alignment type IP material. However, either of the alignment materials has its own drawback. The rubbing alignment type IP material is to form the alignment film with Rubbing method. The Rubbing method is to use fabric roller to perform contacting directional mechanical friction on the macromolecular PI film surface. The energy provided by rubbing the macromolecular surface make the macromolecular main chain be aligned in direction due to the extension, and thus the interaction of the branch and the LC is controlled to align the LC in the direction of the pre-tilted angle; as rubbing, the issues of powder particles, residual electrostatic and brush marks reduce the process yield. The lighting alignment type IP material is to form the alignment film with photo-alignment technology. The photo-alignment technology is to utilize the photochemical reaction of the ultraviolet light polymer monomers to create the anisotropy, and the liquid crystal molecules and the alignment film surface branch interact with each other. For reaching the stable status of the minimum energy, the liquid crystal molecules are aligned along the direction of which the acted force is the maximum defined by the lighting alignment. The lighting alignment type IP material can solve the aforesaid problems but with the restriction of the material properties, the heat resistance and the aging resistance are poor, and meanwhile, the LC anchoring ability is weaker, the quality of the panel is influenced. Besides, the PI material itself has high polarity and high water absorption. The storage and the delivery can easily change the property to result in the nonuniform alignment. The price of the PI material is expensive, and the film formation process on the TFT-LCD is more complicated, which leads to the increase of the panel cost.

### SUMMARY OF THE INVENTION

An objective of the present invention is to provide a manufacture method of a liquid crystal display panel, in which the graphene/PEDOT:PSS composite transparent conductive films replace the traditional ITO transparent conductive films on the TFT substrate and the CF substrate, and meanwhile, a polar material is mixed in the liquid crystal compound to replace the PI alignment films for achieving the result that the liquid crystal molecules are vertically aligned, and thus to manufacture a liquid crystal display panel capable of eliminating the PI alignment films.

For realizing the aforesaid objective, the present invention provides a manufacture method of a liquid crystal display panel, comprising steps of:

step 1, providing a TFT substrate and a CF substrate, and a first conductive film and a second conductive film are respectively formed on one sides of the TFT substrate and the CF substrate, and both the first conductive film and the second conductive film are graphene/PEDOT:PSS composite transparent conductive films;

step 2, mixing polar material into liquid crystal material to obtain liquid crystal compound;

a structural formula of the polar material is A-B, wherein

A is one or more polar groups connected to B, and the polar group is primary amine, secondary amine, tertiary amine, —OH, —COOH, —SH, —Si(CH3)3 or —CN;

B is a linear or chain branched alkyl having 5-20 C atoms, and a first group obtained after some CH₂ group in the alkyl is replaced by phenyl, cycloalkyl, —O—,—CONH—,—COO—,—O—CO—, —CO— or —CH═CH— group, a second group obtained after some H atom in the alkyl is replaced by F atom or Cl atom, or a third group obtained after some H atom in the first group is replaced by F atom or Cl atom;

step 3, employing one drop filling to drop the liquid crystal compound obtained in the step 2 on the one side of the TFT substrate where the first conductive film is or the one side of the CF substrate where the second conductive film is;

step 4, oppositely vacuum laminating the TFT substrate and the CF substrate to obtain the liquid crystal display panel; then, the polar material generates a stronger intermolecular force with the first conductive film on the TFT substrate and the second conductive film on the CF substrate, and is vertically aligned on surfaces of the TFT substrate and the CF substrate, and then liquid crystal molecules in the liquid crystal material are vertically aligned to act a function of liquid crystal alignment.

A structural formula of the polar material is:

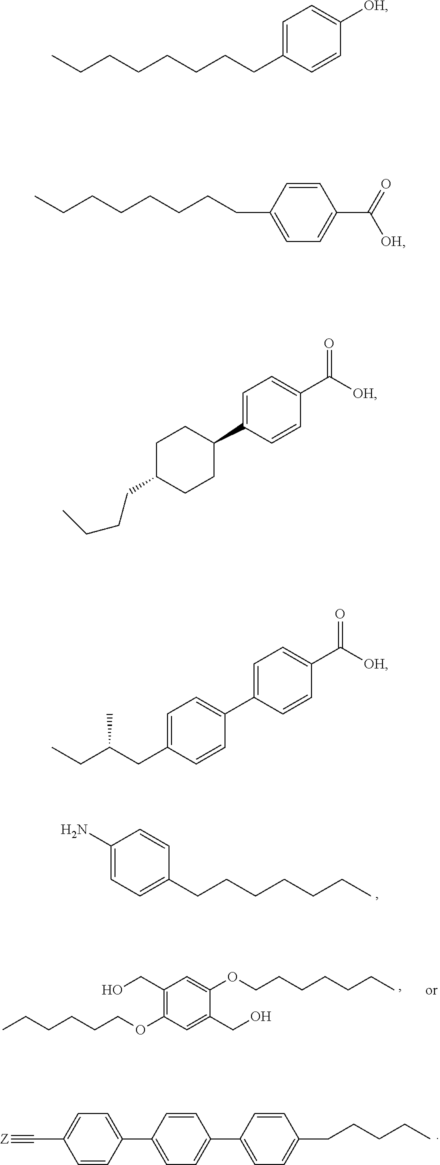

In the liquid crystal compound obtained in the step 2, a content of the polar material is 0.1˜5 wt %.

A plurality of roof shape projections are respectively provided on the one sides of the TFT substrate and the CF substrate provided in the step 1 where the first conductive film and the second conductive film are pre-formed.

The step 1 specifically comprises steps of:

step 11, putting graphene powder and water surfactant into deionized water and performing ultrasonic dispersion to the same according to a mass ratio of the graphene powder, the water surfactant and the deionized water with 1:50-500:2000-100000 to obtain graphene solution;

step 12, mixing the graphene solution and PEDOT:PSS solution of a certain concentration according to a mass ratio of 1:100 to 100:1 and obtaining graphene/PEDOT:PSS mixed solution which is uniformly distributed after the ultrasonic dispersion;

step 13, employing wet coating to coat the graphene/PEDOT:PSS mixed solution on the TFT substrate and the CF substrate respectively to perform film formation to obtain graphene/PEDOT:PSS thin films;

step 14, employing the deionized water to wash the TFT substrate and the CF substrate after film formation to remove the water surfactant in the graphene/PEDOT:PSS thin films to increase conductivity of the graphene/PEDOT:PSS thin films;

step 15, drying the graphene/PEDOT:PSS thin films to remove water in the thin films to obtain the graphene/PEDOT:PSS composite conductive films, which respectively are the first conductive film on the one side of the TFT substrate and the second conductive film on the one side of the CF substrate.

In the step 11, the water surfactant is sodium dodecyl sulfate, ammonium dodecyl sulfate, sodium dodecyl sulfonate, sodium dodecyl benzene sulfonate or sodium tetradecyl sulfate; an ultrasonic generator is employed to perform the ultrasonic dispersion, and an ultrasonic power is 50-400 W, and an ultrasonic duration is 5-60 min.

In the step 12, the PEDOT:PSS solution is prepared with the deionized water and the PEDOT:PSS, and a mass percentage of the PEDOT:PSS in the PEDOT:PSS solution is 1-100 wt %.

In the step 13, the wet coating is spray coating, spin coating, roller coating, slot-die coating, dip coating, knife coating, gravure printing, ink jet printing or screen printing.

As the wet coating is spray coating, and the step 13 is: positioning the TFT substrate and the CF substrate on a constant temperature heating plate, and employing the spray coating to coat the graphene/PEDOT:PSS mixed solution on the TFT substrate and the CF substrate to perform the film formation to obtain the graphene/PEDOT:PSS thin films, and a temperature range of the constant temperature heating plate is 80-120° C.;

as the wet coating is spin coating, roller coating or slot-die coating, the step 13 is: coating the graphene/PEDOT:PSS mixed solution on the TFT substrate and the CF substrate, and the TFT substrate and the CF substrate are quickly transferred on the constant temperature heating plate to be baked with 3-10 min to perform the film formation to obtain the graphene/PEDOT:PSS thin films, and a temperature range of the constant temperature heating plate is 80-140° C.

The drying in the step 15 is natural drying, nitrogen blow drying or fast stoving of heating condition 80-120° C.

The present invention further provides a manufacture method of a liquid crystal display panel, comprising steps of:

step 1, providing a TFT substrate and a CF substrate, and a first conductive film and a second conductive film are respectively formed on one sides of the TFT substrate and the CF substrate, and both the first conductive film and the second conductive film are graphene/PEDOT:PSS composite transparent conductive films;

step 2, mixing polar material into liquid crystal material to obtain liquid crystal compound;

a structural formula of the polar material is A-B, wherein

A is one or more polar groups connected to B, and the polar group is primary amine, secondary amine, tertiary amine, —OH, —COOH, —SH, —Si(CH3)3 or —CN;

B is a linear or chain branched alkyl having 5-20 C atoms, and a first group obtained after some CH₂ group in the alkyl is replaced by phenyl, cycloalkyl, —O—,—CONH—,—COO—,—O—CO—,—CO— or —CH═CH— group, a second group obtained after some H atom in the alkyl is replaced by F atom or Cl atom, or a third group obtained after some H atom in the first group is replaced by F atom or Cl atom;

step 3, employing one drop filling to drop the liquid crystal compound obtained in the step 2 on the one side of the TFT substrate where the first conductive film is or the one side of the CF substrate where the second conductive film is;

step 4, oppositely vacuum laminating the TFT substrate and the CF substrate to obtain the liquid crystal display panel; then, the polar material generates a stronger intermolecular force with the first conductive film on the TFT substrate and the second conductive film on the CF substrate, and is vertically aligned on surfaces of the TFT substrate and the CF substrate, and then liquid crystal molecules in the liquid crystal material are vertically aligned to act a function of liquid crystal alignment;

wherein a structural formula of the polar material is:

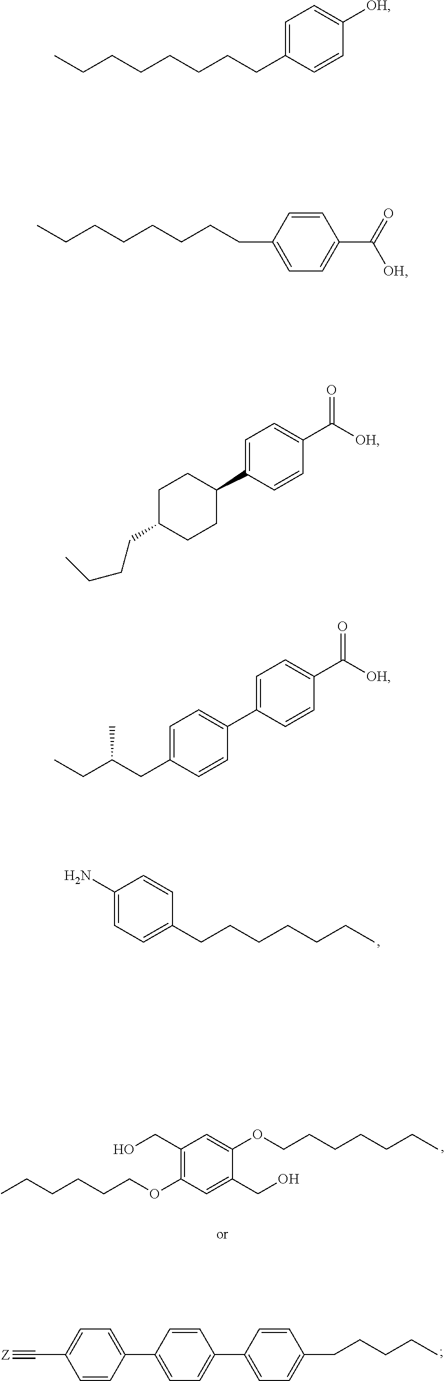

wherein in the liquid crystal compound obtained in the step 2, a content of the polar material is 0.1˜5 wt %;

wherein a plurality of roof shape projections are respectively provided on the one sides of the TFT substrate and the CF substrate provided in the step 1 where the first conductive film and the second conductive film are pre-formed.

The benefits of the present invention are: the present invention provides the manufacture method of the liquid crystal display panel. The graphene/PEDOT:PSS composite transparent conductive films replace the traditional ITO transparent conductive films on the TFT substrate and the CF substrate, and meanwhile, a polar material is mixed in the liquid crystal compound of the liquid crystal display panel. The structural formula of the polar material is A-B, wherein A is one or more polar groups connected to B, and the polar group is primary amine, secondary amine, tertiary amine, —OH, —COOH, —SH, —Si(CH3)3 or —CN; B is a linear or chain branched alkyl having 5-20 C atoms, and a first group obtained after some CH₂ group in the alkyl is replaced by phenyl, cycloalkyl, —O—,—CONH—,—COO—,—O—CO—, —CO— or —CH═CH— group, a second group obtained after some H atom in the alkyl is replaced by F atom or Cl atom, or a third group obtained after some H atom in the first group is replaced by F atom or Cl atom; the polar material can generate a larger intermolecular force with the graphene/PEDOT:PSS composite transparent conductive films, and is vertically aligned on the graphene/PEDOT:PSS composite transparent conductive films, wherein the main function of the head group A is to create the larger intermolecular force between the polar material and the graphene/PEDOT:PSS composite transparent conductive films, and the main function of the tail group B is similar with the function of the PI branch to vertically align the liquid crystal molecules in the steric hindrance manner. Thus, it can replace the PI alignment films to act the effect of the vertical alignment to eliminate the PI alignment film process for reducing the production cost of the alignment film and raising the productivity.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a flow chart of a manufacture method of a liquid crystal display panel according to the present invention;

FIG. 2 is a structure diagram of polar material provided in the step 2 in the manufacture method of the liquid crystal display panel according to the present invention;

FIG. 3 is a diagram of interaction between the polar material and the graphene/PEDOT:PSS composite transparent conductive films in the manufacture method of the liquid crystal display panel according to the present invention;

FIG. 4 is a diagram of the step 4 in the manufacture method of the liquid crystal display panel according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

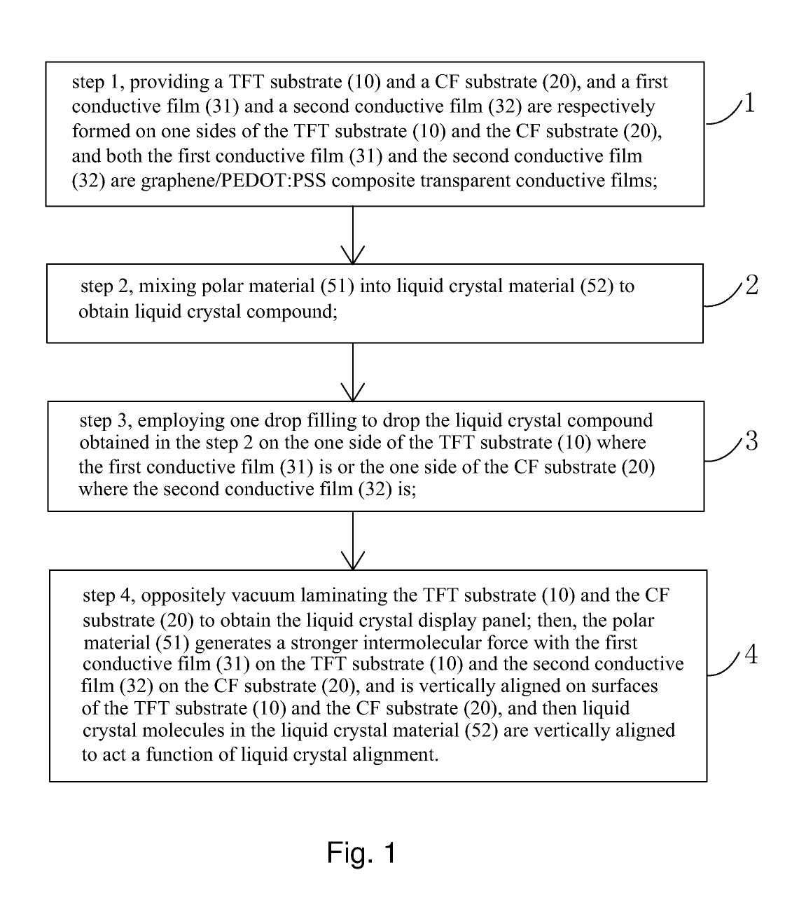

Please refer to FIG. 1. The present invention provides a manufacture method of a liquid crystal display panel, comprising steps of:

step 1, providing a TFT substrate 10 and a CF substrate 20, and a first conductive film 31 and a second conductive film 32 are respectively formed on one sides of the TFT substrate 10 and the CF substrate 20, and both the first conductive film 31 and the second conductive film 32 are graphene/PEDOT:PSS composite transparent conductive films.

Specifically, the liquid crystal display panel is a multi-domain vertical alignment (MVA) type liquid crystal display panel, and the TFT substrate 10 and the CF substrate 20 provided in the step 2 is a TFT substrate and a CF substrate of the traditional MVA type liquid crystal display panel, and a plurality of roof shape projections 21 are provided respectively on the one sides of the TFT substrate 10 and the CF substrate 20 where the first conductive film 31 and the second conductive film 32 are pre-formed.

Specifically, the first conductive film 31 is employed for the pixel electrodes of the TFT substrate 10, and the second conductive film 32 is employed for the common electrode of the CF substrate 20.

step 2, mixing polar material 51 into liquid crystal material 52 to obtain liquid crystal compound;

a structural formula of the polar material 51 is A-B, wherein

A is one or more polar groups connected to B, and the polar group is primary amine, secondary amine, tertiary amine, —OH, —COOH, —SH, —Si(CH3)3 or —CN;

B is a linear or chain branched alkyl having 5-20 C atoms, and a first group obtained after some CH₂ group in the alkyl is replaced by phenyl, cycloalkyl, —O—,—CONH—,—COO—,—O—CO— or —CH═CH— group, a second group obtained after some H atom in the alkyl is replaced by F atom or Cl atom, or a third group obtained after some H atom in the first group is replaced by F atom or Cl atom.

Preferably, a structural formula of the polar material 51 is:

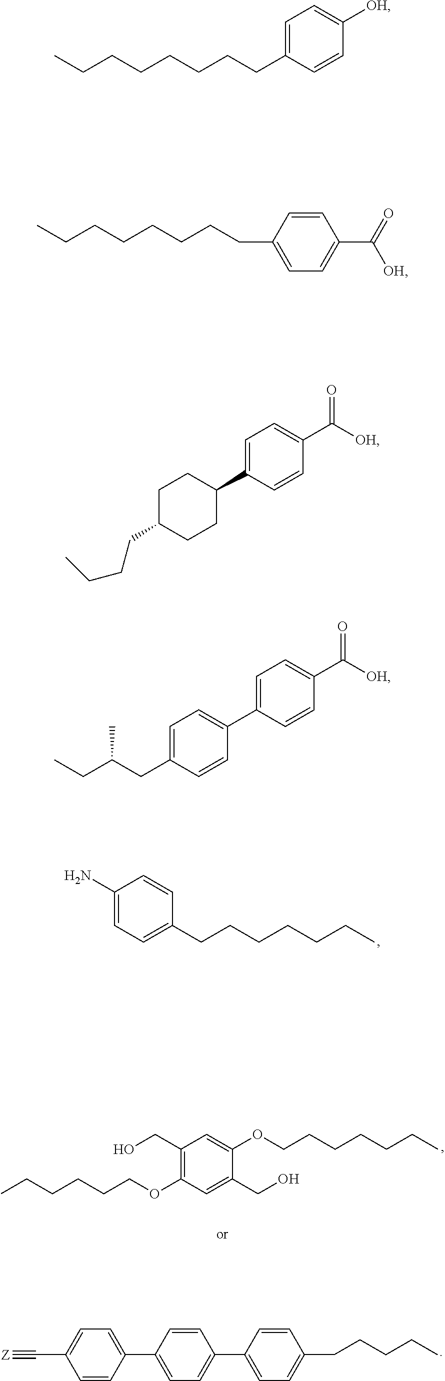

Specifically, in the liquid crystal compound obtained in the step 2, a content of the polar material 51 is 0.1˜5 wt %.

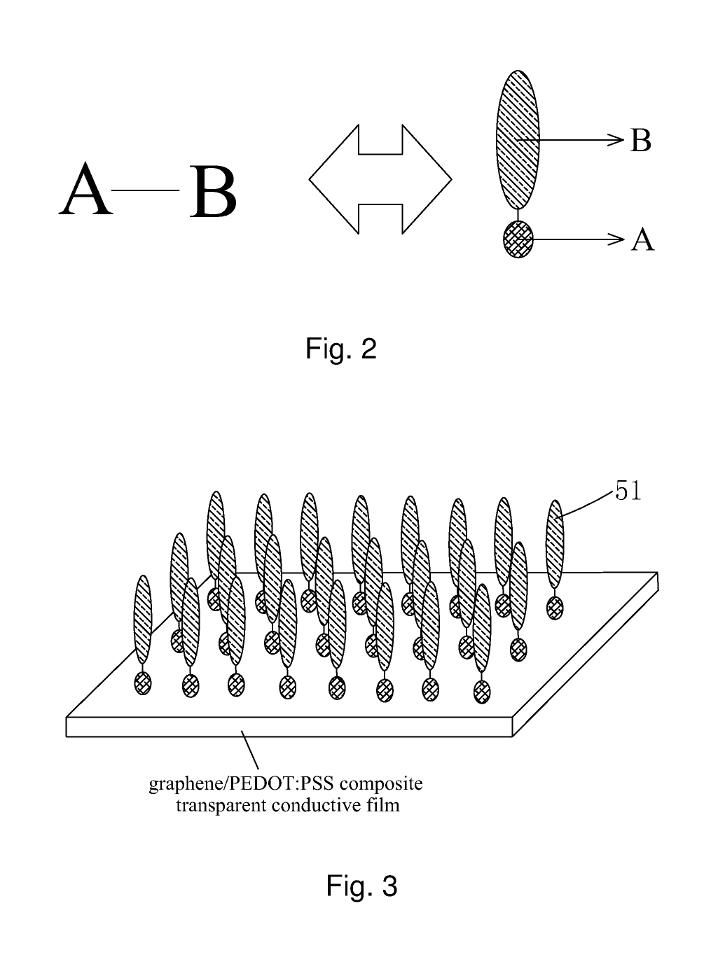

Specifically, as shown in FIGS. 2-3, in the polar material 51, A is one or more polar groups, in which the main function of the head group A is to create the stronger intermolecular force between the polar material 51 and the graphene/PEDOT:PSS composite transparent conductive films, and the material is adhered on the graphene/PEDOT:PSS composite transparent conductive films; and the main function of the tail group B is similar with the function of the PI branch to vertically align the liquid crystal molecules in the steric hindrance manner.

Specifically, the action mechanism between the polar material 51 and the graphene/PEDOT:PSS composite transparent conductive films is:

(1) graphene is a net structure formed by carbon atoms in SP2 hybridization, wherein only one P orbit electron remains in the structure, and the electrons of the benzene ring in the structure will have stronger intermolecular force with the polar material 51 containing the polar groups;

(2) PEDOT is Poly(3,4-ethylenedioxythiophene), wherein the thiophene itself inside is also an electron rich group, which also will generate stronger intermolecular force with the polar material 51 containing the polar groups;

(3) PSS is Poly(sodium-p-styrenesulfonate), which does not only comprise the benzene ring structure but also the sulfo group, which also will generate stronger intermolecular force with the polar material 51 containing the polar groups.

step 3, employing one drop filling (ODF) to drop the obtained liquid crystal compound on the one side of the TFT substrate 10 where the first conductive film 31 is or the one side of the CF substrate 20 where the second conductive film 32 is.

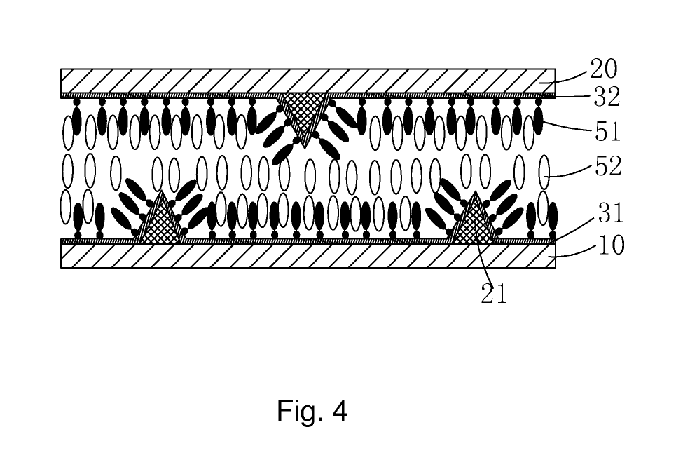

step 4, as shown in FIG. 4, oppositely vacuum laminating the TFT substrate 10 and the CF substrate 20 to obtain the liquid crystal display panel; then, the polar material 51 generates a stronger intermolecular force with the first conductive film 31 on the TFT substrate 10 and the second conductive film 32 on the CF substrate 20, and is vertically aligned on surfaces of the TFT substrate 10 and the CF substrate 20, and then liquid crystal molecules in the liquid crystal material 52 are vertically aligned to act a function of liquid crystal alignment. Furthermore, because a plurality of roof shape projections 21 are provided on the TFT substrate 10 and the CF substrate 20, the polar material 51 above the projections 21 are vertically aligned along the bevels of the projections 21. Thus, the liquid crystal molecules in the liquid crystal material 52 are guided to be vertically aligned along the bevels of the projections 21, and the liquid crystal molecules have the pre-tilted angle.

The step 1 specifically comprises steps of:

step 11, putting graphene powder and water surfactant into deionized water and performing ultrasonic dispersion to the same according to a mass ratio of the graphene powder, the water surfactant and the deionized water with 1:50-500:2000-100000 to obtain graphene solution;

Specifically, the water surfactant is sodium dodecyl sulfate, ammonium dodecyl sulfate, sodium dodecyl sulfonate, sodium dodecyl benzene sulfonate or sodium tetradecyl sulfate.

Specifically, an ultrasonic generator is employed to perform the ultrasonic dispersion, and an ultrasonic power is 50-400 W, and an ultrasonic duration is 5-60 min.

step 12, mixing the graphene solution and PEDOT:PSS solution of a certain concentration according to a mass ratio of 1:100 to 100:1 and obtaining graphene/PEDOT:PSS mixed solution which is uniformly distributed after the ultrasonic dispersion;

specifically, the PEDOT:PSS solution is prepared with the deionized water and the PEDOT:PSS, and a mass percentage of the PEDOT:PSS in the PEDOT:PSS solution is 1-100 wt %.

step 13, employing wet coating to coat the graphene/PEDOT:PSS mixed solution on the TFT substrate 10 and the CF substrate 20 respectively to perform film formation to obtain graphene/PEDOT:PSS thin films;

Specifically, the wet coating is spray coating, spin coating, roller coating, slot-die coating, dip coating, knife coating, gravure printing, ink jet printing or screen printing.

Specifically, as the wet coating is spray coating, and the step 13 is: positioning the TFT substrate 10 and the CF substrate 20 on a constant temperature heating plate, and employing the spray coating to coat the graphene/PEDOT:PSS mixed solution on the TFT substrate 10 and the CF substrate 20 to perform the film formation to obtain the graphene/PEDOT:PSS thin films, and a temperature range of the constant temperature heating plate is 80-120° C.

Specifically, as utilizing the spray coating, the factors, such as the usage volume of the graphene/PEDOT:PSS mixed solution, the spray pressure, duration and times can be controlled to control the thickness of the film formation.

As the wet coating is spin coating, roller coating or slot-die coating, the step 13 is: coating the graphene/PEDOT:PSS mixed solution on the TFT substrate 10 and the CF substrate 20, and the TFT substrate 10 and the CF substrate 20 are quickly transferred on the constant temperature heating plate to be baked with 3-10 min to perform the film formation to obtain the graphene/PEDOT:PSS thin films, and a temperature range of the constant temperature heating plate is 80-140° C.

Specifically, as utilizing the spin coating, the factors, such as the usage volume of the graphene/PEDOT:PSS mixed solution, the spin duration, speed and times can be controlled to control the thickness of the film formation.

step 14, employing the deionized water to wash the TFT substrate 10 and the CF substrate 20 after film formation to remove the water surfactant in the graphene/PEDOT:PSS thin films to increase conductivity of the graphene/PEDOT:PSS thin films;

step 15, drying the graphene/PEDOT:PSS thin films to remove water in the thin films to obtain the graphene/PEDOT:PSS composite conductive films, which respectively are the first conductive film 31 on the one side of the TFT substrate 10 and the second conductive film 32 on the one side of the CF substrate 20.

Specifically, the drying process is natural drying, nitrogen blow drying or fast stoving of heating condition 80-120° C.

In conclusion, in the manufacture method of the liquid crystal display panel, according to the present invention, the graphene/PEDOT:PSS composite transparent conductive films replace the traditional ITO transparent conductive films on the TFT substrate and the CF substrate, and meanwhile, a polar material is mixed in the liquid crystal compound of the liquid crystal display panel. The structural formula of the polar material is A-B, wherein A is one or more polar groups connected to B, and the polar group is primary amine, secondary amine, tertiary amine, —OH, —COOH, —SH, —Si(CH3)3 or —CN; B is a linear or chain branched alkyl having 5-20 C atoms, and a first group obtained after some CH₂ group in the alkyl is replaced by phenyl, cycloalkyl, —O—,—CONH—,—COO—,—O—CO— or —CH═CH— group, a second group obtained after some H atom in the alkyl is replaced by F atom or Cl atom, or a third group obtained after some H atom in the first group is replaced by F atom or Cl atom; the polar material can generate a larger intermolecular force with the graphene/PEDOT:PSS composite transparent conductive films, and is vertically aligned on the graphene/PEDOT:PSS composite transparent conductive films, wherein the main function of the head group A is to create the larger intermolecular force between the polar material and the graphene/PEDOT:PSS composite transparent conductive films, and the main function of the tail group B is similar with the function of the PI branch to vertically align the liquid crystal molecules in the steric hindrance manner. Thus, it can replace the PI alignment films to act the effect of the vertical alignment to eliminate the PI alignment film process for reducing the production cost of the alignment film and raising the productivity.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of a liquid crystal display panel, comprising steps of:
step 1, providing a TFT substrate and a CF substrate, and a first conductive film and a second conductive film are respectively formed on one sides of the TFT substrate and the CF substrate, and both the first conductive film and the second conductive film are graphene/PEDOT:PSS composite transparent conductive films;
step 2, mixing polar material into liquid crystal material to obtain liquid crystal compound;
a structural formula of the polar material is A-B, wherein
A is one or more polar groups connected to B, and the polar group is primary amine, secondary amine, tertiary amine, —OH, —COOH, —SH, —Si(CH3)3 or —CN;
B is a linear or chain branched alkyl having 5-20 C atoms, and a first group obtained after some CH₂ group in the alkyl is replaced by phenyl, cycloalkyl, —O—,—CONH—,—COO—,—O—CO— or —CH═CH— group, a second group obtained after some H atom in the alkyl is replaced by F atom or Cl atom, or a third group obtained after some H atom in the first group is replaced by F atom or Cl atom;
step 3, employing one drop filling to drop the liquid crystal compound obtained in the step 2 on the one side of the TFT substrate where the first conductive film is or the one side of the CF substrate where the second conductive film is;
step 4, oppositely vacuum laminating the TFT substrate and the CF substrate to obtain the liquid crystal display panel; then, the polar material generates a stronger intermolecular force with the first conductive film on the TFT substrate and the second conductive film on the CF substrate, and is vertically aligned on surfaces of the TFT substrate and the CF substrate, and then liquid crystal molecules in the liquid crystal material are vertically aligned to act a function of liquid crystal alignment.

2. The manufacture method of the liquid crystal display panel according to claim 1, wherein a structural formula of the polar material is:

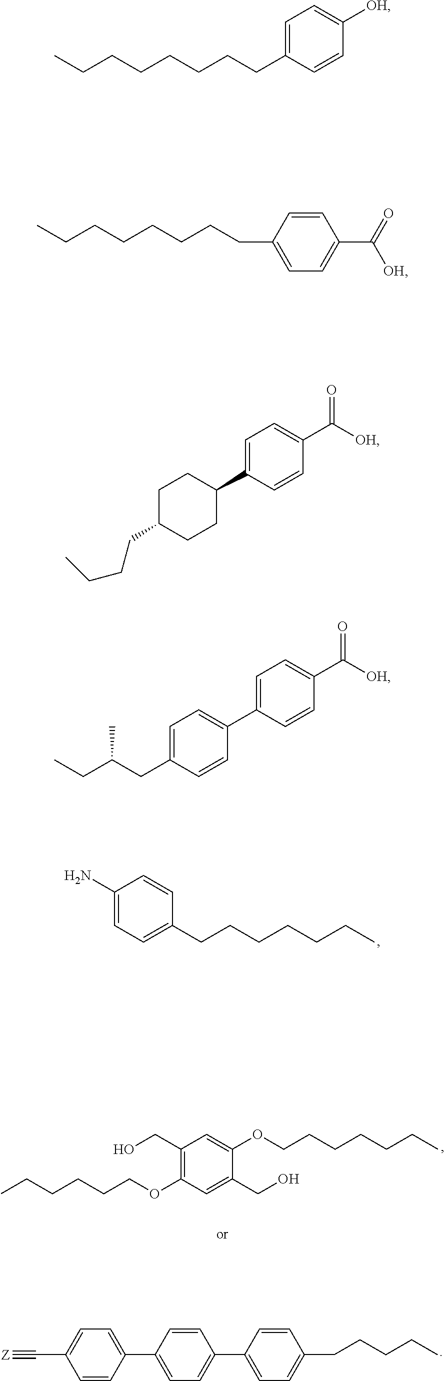

3. The manufacture method of the liquid crystal display panel according to claim 1, wherein in the liquid crystal compound obtained in the step 2, a content of the polar material is 0.1˜5 wt %.

4. The manufacture method of the liquid crystal display panel according to claim 1, wherein a plurality of roof shape projections are respectively provided on the one sides of the TFT substrate and the CF substrate provided in the step 1 where the first conductive film and the second conductive film are pre-formed.

5. The manufacture method of the liquid crystal display panel according to claim 1, wherein the step 1 specifically comprises steps of:
step 11, putting graphene powder and water surfactant into deionized water and performing ultrasonic dispersion to the same according to a mass ratio of the graphene powder, the water surfactant and the deionized water with 1:50-500:2000-100000 to obtain graphene solution;
step 12, mixing the graphene solution and PEDOT:PSS solution of a certain concentration according to a mass ratio of 1:100 to 100:1 and obtaining graphene/PEDOT:PSS mixed solution which is uniformly distributed after the ultrasonic dispersion;
step 13, employing wet coating to coat the graphene/PEDOT:PSS mixed solution on the TFT substrate and the CF substrate respectively to perform film formation to obtain graphene/PEDOT:PSS thin films;
step 14, employing the deionized water to wash the TFT substrate and the CF substrate after film formation to remove the water surfactant in the graphene/PEDOT:PSS thin films to increase conductivity of the graphene/PEDOT:PSS thin films;
step 15, drying the graphene/PEDOT:PSS thin films to remove water in the thin films to obtain the graphene/PEDOT:PSS composite conductive films, which respectively are the first conductive film on the one side of the TFT substrate and the second conductive film on the one side of the CF substrate.

6. The manufacture method of the liquid crystal display panel according to claim 5, wherein in the step 11, the water surfactant is sodium dodecyl sulfate, ammonium dodecyl sulfate, sodium dodecyl sulfonate, sodium dodecyl benzene sulfonate or sodium tetradecyl sulfate; an ultrasonic generator is employed to perform the ultrasonic dispersion, and an ultrasonic power is 50-400 W, and an ultrasonic duration is 5-60 min.

7. The manufacture method of the liquid crystal display panel according to claim 5, wherein in the step 12, the PEDOT:PSS solution is prepared with the deionized water and the PEDOT:PSS, and a mass percentage of the PEDOT:PSS in the PEDOT:PSS solution is 1-100 wt %.

8. The manufacture method of the liquid crystal display panel according to claim 5, wherein in the step 13, the wet coating is spray coating, spin coating, roller coating, slot-die coating, dip coating, knife coating, gravure printing, ink jet printing or screen printing.

9. The manufacture method of the liquid crystal display panel according to claim 8, wherein as the wet coating is spray coating, and the step 13 is: positioning the TFT substrate and the CF substrate on a constant temperature heating plate, and employing the spray coating to coat the graphene/PEDOT:PSS mixed solution on the TFT substrate and the CF substrate to perform the film formation to obtain the graphene/PEDOT:PSS thin films, and a temperature range of the constant temperature heating plate is 80-120° C.;
as the wet coating is spin coating, roller coating or slot-die coating, the step 13 is: coating the graphene/PEDOT:PSS mixed solution on the TFT substrate and the CF substrate, and the TFT substrate and the CF substrate are quickly transferred on the constant temperature heating plate to be baked with 3-10 min to perform the film formation to obtain the graphene/PEDOT:PSS thin films, and a temperature range of the constant temperature heating plate is 80-140° C.

10. The manufacture method of the liquid crystal display panel according to claim 5, wherein the drying in the step 15 is natural drying, nitrogen blow drying or fast stoving of heating condition 80-120° C.

11. A manufacture method of a liquid crystal display panel, comprising steps of:
step 1, providing a TFT substrate and a CF substrate, and a first conductive film and a second conductive film are respectively formed on one sides of the TFT substrate and the CF substrate, and both the first conductive film and the second conductive film are graphene/PEDOT:PSS composite transparent conductive films;
step 2, mixing polar material into liquid crystal material to obtain liquid crystal compound;
a structural formula of the polar material is A-B, wherein
A is one or more polar groups connected to B, and the polar group is primary amine, secondary amine, tertiary amine, —OH, —COOH, —SH, —Si(CH3)3 or —CN;
B is a linear or chain branched alkyl having 5-20 C atoms, and a first group obtained after some CH₂ group in the alkyl is replaced by phenyl, cycloalkyl, —O—,—CONH—,—COO—,—O—CO— or —CH═CH— group, a second group obtained after some H atom in the alkyl is replaced by F atom or Cl atom, or a third group obtained after some H atom in the first group is replaced by F atom or Cl atom;
step 3, employing one drop filling to drop the liquid crystal compound obtained in the step 2 on the one side of the TFT substrate where the first conductive film is or the one side of the CF substrate where the second conductive film is;
step 4, oppositely vacuum laminating the TFT substrate and the CF substrate to obtain the liquid crystal display panel; then, the polar material generates a stronger intermolecular force with the first conductive film on the TFT substrate and the second conductive film on the CF substrate, and is vertically aligned on surfaces of the TFT substrate and the CF substrate, and then liquid crystal molecules in the liquid crystal material are vertically aligned to act a function of liquid crystal alignment;
wherein a structural formula of the polar material is: 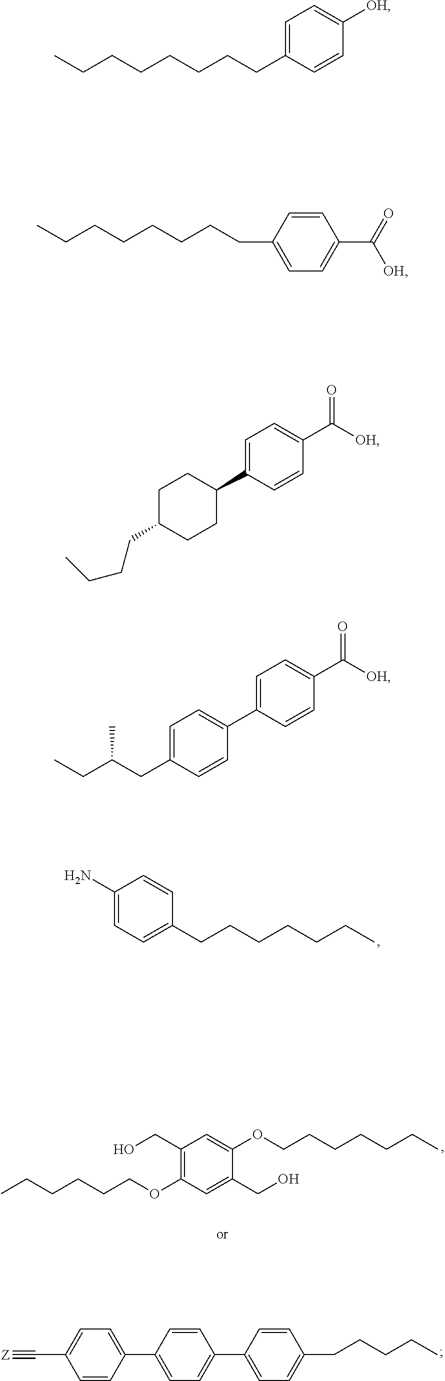
wherein in the liquid crystal compound obtained in the step 2, a content of the polar material is 0.1˜5 wt %;
wherein a plurality of roof shape projections are respectively provided on the one sides of the TFT substrate and the CF substrate provided in the step 1 where the first conductive film and the second conductive film are pre-formed.

12. The manufacture method of the liquid crystal display panel according to claim 11, wherein the step 1 specifically comprises steps of:
step 11, putting graphene powder and water surfactant into deionized water and performing ultrasonic dispersion to the same according to a mass ratio of the graphene powder, the water surfactant and the deionized water with 1:50-500:2000-100000 to obtain graphene solution;
step 12, mixing the graphene solution and PEDOT:PSS solution of a certain concentration according to a mass ratio of 1:100 to 100:1 and obtaining graphene/PEDOT:PSS mixed solution which is uniformly distributed after the ultrasonic dispersion;
step 13, employing wet coating to coat the graphene/PEDOT:PSS mixed solution on the TFT substrate and the CF substrate respectively to perform film formation to obtain graphene/PEDOT:PSS thin films;
step 14, employing the deionized water to wash the TFT substrate and the CF substrate after film formation to remove the water surfactant in the graphene/PEDOT:PSS thin films to increase conductivity of the graphene/PEDOT:PSS thin films;
step 15, drying the graphene/PEDOT:PSS thin films to remove water in the thin films to obtain the graphene/PEDOT:PSS composite conductive films, which respectively are the first conductive film on the one side of the TFT substrate and the second conductive film on the one side of the CF substrate.

13. The manufacture method of the liquid crystal display panel according to claim 12, wherein in the step 11, the water surfactant is sodium dodecyl sulfate, ammonium dodecyl sulfate, sodium dodecyl sulfonate, sodium dodecyl benzene sulfonate or sodium tetradecyl sulfate; an ultrasonic generator is employed to perform the ultrasonic dispersion, and an ultrasonic power is 50 -400W, and an ultrasonic duration is 5-60 min.

14. The manufacture method of the liquid crystal display panel according to claim 12, wherein in the step 12, the PEDOT:PSS solution is prepared with the deionized water and the PEDOT:PSS, and a mass percentage of the PEDOT:PSS in the PEDOT:PSS solution is 1-100 wt %.

15. The manufacture method of the liquid crystal display panel according to claim 12, wherein in the step 13, the wet coating is spray coating, spin coating, roller coating, slot-die coating, dip coating, knife coating, gravure printing, ink jet printing or screen printing.

16. The manufacture method of the liquid crystal display panel according to claim 15, wherein as the wet coating is spray coating, and the step 13 is: positioning the TFT substrate and the CF substrate on a constant temperature heating plate, and employing the spray coating to coat the graphene/PEDOT:PSS mixed solution on the TFT substrate and the CF substrate to perform the film formation to obtain the graphene/PEDOT:PSS thin films, and a temperature range of the constant temperature heating plate is 80-120° C.;
as the wet coating is spin coating, roller coating or slot-die coating, the step 13 is: coating the graphene/PEDOT:PSS mixed solution on the TFT substrate and the CF substrate, and the TFT substrate and the CF substrate are quickly transferred on the constant temperature heating plate to be baked with 3-10 min to perform the film formation to obtain the graphene/PEDOT:PSS thin films, and a temperature range of the constant temperature heating plate is 80-140° C.

17. The manufacture method of the liquid crystal display panel according to claim 12, wherein the drying in the step 15 is natural drying, nitrogen blow drying or fast stoving of heating condition 80-120° C.
